(19) United States
(12) Patent Application Publication
(10) Pub. No.: US 2012/0012148 A1
(43) Pub. Date: Jan. 19, 2012

(54) HIGH SURFACE AREA PHOTOVOLTAIC SYSTEMS

(75) Inventor: Majid Tabatabai, San Jose, CA (US)

(73) Assignee: Sunsera, Inc., San Jose, CA (US)

(21) Appl. No.: 12/839,313

(22) Filed: Jul. 19, 2010

(51) Int. Cl. H01L 31/042; H01L 31/0203

(52) U.S. Cl. 136/244; 136/259

(57) ABSTRACT

A high-surface area photovoltaic device is disclosed. A photovoltaic module created in accordance with the disclosed technique can include a three-dimensional multi-cell photovoltaic structure, a multi-three-dimensional cell photovoltaic structure, or a polyhedron formed with photovoltaic cells. Photovoltaic cells can be arranged along a three-dimensional surface cover of the photovoltaic device. The photovoltaic device can include internally-reflective surfaces to at least in part contain light within the photovoltaic device. A monolithic lens can be used to focus light on a photovoltaic cell within the photovoltaic device.

### BACKGROUND

A photovoltaic cell is a device that converts energy of light into electricity through the photovoltaic effect. Sometimes the term solar cell is used to describe a photovoltaic cell that is intended specifically to capture energy from sunlight. So a photovoltaic cell is more general, if not in technical implementation, then at least in use. Photovoltaic cells often use rigid wafer-based crystalline silicon cells or a more flexible thin-film cell based on cadmium telluride or silicon, but this is an area of active innovation and other materials are currently in use, and still others are likely to be developed. Photovoltaic cells must be protected from corrosion and mechanical damage at various stages of deployment, including at manufacture, transport, installation, and use in a given environment.

In order to use photovoltaic cells in practical applications, they must generally be electrically coupled to one another and the rest of the system. The coupling can be in series to achieve a desired output voltage and/or in parallel to provide a particular current source capability.

Assemblies of photovoltaic cells are used to make panels or modules. Photovoltaic modules often have a sheet of glass on the top of the panel that is to face the light source, which allows light to pass through while protecting the cells from the elements. The structural (load carrying) member of a photovoltaic module can either be the front (light-facing) layer, or superstrate, or the back layer, or substrate. The superstrate is transparent to allow light to pass through.

Photovoltaic panels or modules can be assembled to make photovoltaic arrays. A photovoltaic installation typically includes at least one photovoltaic panel or module, an inverter for feeding electricity into the grid, and interconnection wiring. For stand-alone systems, batteries are used to store energy that is not currently needed.

There are ongoing efforts to improve the efficiency of solar cells. Some attempts have included module design features to decrease temperature because cell heating typically reduces operating efficiency. However, most installers simply try to provide ventilation behind a photovoltaic module because of the expense of implementing a cooling system. Other attempts include concentrator modules that are designed to concentrate light by an array of lenses or mirrors onto an array of photovoltaic cells. While this has had some success when using high-cost per unit area cells, such as those made with gallium arsenide, concentrator modules are generally too expensive to be cost-competitive and those that are cost-competitive typically have to make use of a large area of lenses or mirrors to focus light and require high precision tracking systems to aim the light. Yet other attempts have included covering a broader range of frequencies of light, implementing infrared cells that work even at night, and splitting light into different wavelength ranges that are directed to cells tuned to the appropriate wavelength ranges.

### SUMMARY

The following is described and illustrated in conjunction with systems, tools, and methods that are meant to be exemplary and illustrative, not limiting in scope. Techniques are described to address one or more of deficiencies in the state of the art.

A high-surface area photovoltaic device is disclosed. A photovoltaic module created in accordance with the disclosed technique can include a three-dimensional multi-cell photovoltaic structure, a multi-three-dimensional cell photovoltaic structure, or a polyhedron formed with photovoltaic cells. Photovoltaic cells can be arranged along a three-dimensional surface cover of the photovoltaic device. The photovoltaic device can include internally-reflective surfaces to at least in part contain light within the photovoltaic device. A monolithic lens can be used to focus light on a photovoltaic cell within the photovoltaic device.

### BRIEF DESCRIPTION OF THE DRAWINGS

Examples of the claimed subject matter are illustrated in the figures.

FIG. 1 depicts an example of a high surface area photovoltaic cell.

FIG. 2 depicts an example of a high surface area photovoltaic cell with superstrate.

FIG. 3 depicts an example of a photovoltaic supercell device.

FIG. 3 depicts an example of a photovoltaic panel with a three-dimensional multi-cell photovoltaic structure.

FIG. 4 depicts an example of a photovoltaic panel with a multi-three-dimensional cell photovoltaic structure.

FIG. 5 depicts an example of a photovoltaic panel with a three-dimensional multi-cell photovoltaic structure and internal reflective surface.

FIG. 6 depicts an example of a photovoltaic panel with a three-dimensional internally-reflective structure.

FIG. 7 depicts an example of a concentrating photovoltaics (CPV) photovoltaic panel.

FIG. 8 depicts an example of a three-dimensional photovoltaic module.

FIG. 9 depicts an example of a tubic photovoltaic module.

FIG. 10 depicts an example of a three-dimensional photovoltaic array.

### DETAILED DESCRIPTION

In the following description, several specific details are presented to provide a thorough understanding of examples of the claimed subject matter. One skilled in the relevant art will recognize, however, that one or more of the specific details can be eliminated or combined with other components, etc. In other instances, well-known implementations or operations are not shown or described in detail to avoid obscuring aspects of the claimed subject matter.

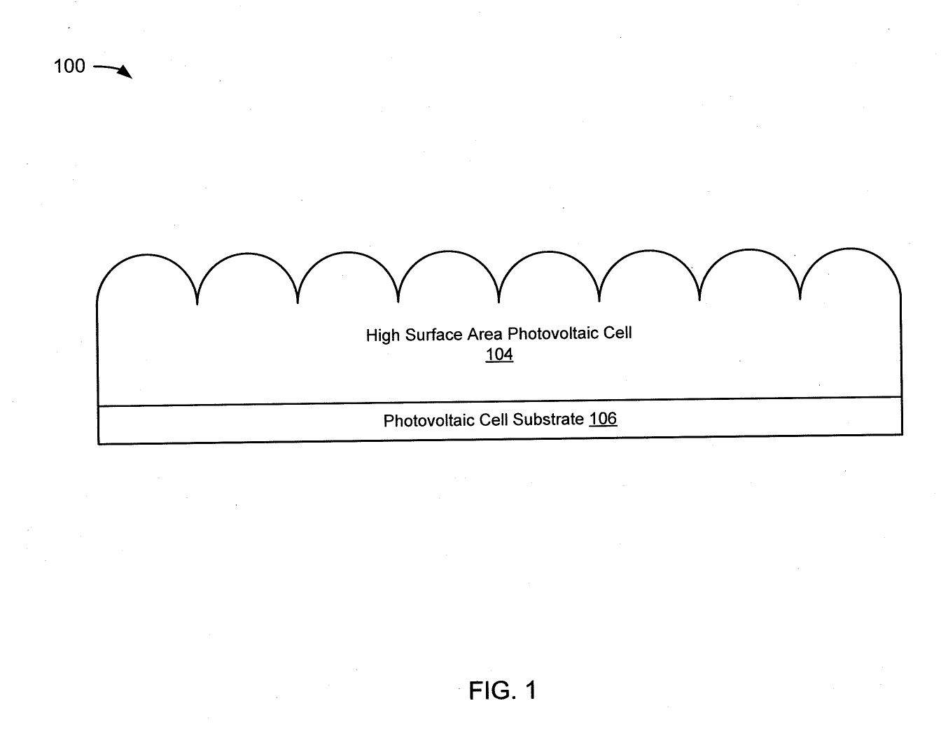

FIG. 1 depicts an example of a high surface area photovoltaic cell device 100. The device 100 includes a high surface area photovoltaic cell 104 and a photovoltaic cell substrate 106. In the example of FIG. 1, the high surface area photovoltaic cell 104 is the portion of the device that, in operation, will be on the light-facing side, which may also be referred to as the top or front, of a photovoltaic module. The shape of the top of the high surface area photovoltaic cell 104 is intended to be illustrative in nature, but various shapes are possible that do not resemble the semi-circular humps that are depicted. The design goal of the shaped surface is to increase the amount of light that hits a surface area of the high surface area photovoltaic cell 104, at least at certain angles of incidence and ideally at all times.

In a specific embodiment, the high surface area photovoltaic cell 104 is a cavitated structure. Advantageously, such a structure could be manufactured using a process that extrudes material that is to form the high surface area photovoltaic cell 104 onto a convex or patterned mold. As is suggested in the example of FIG. 1, the device can have multiple roughly semi-circular cavitations, though it is possible to form the high surface area photovoltaic cell 104 into a single semi-circular cavitation and/or one or more other shapes. Where the high surface area photovoltaic cell 104 has a single cavitation (not shown), the device 100 can be referred to as a photovoltaic supercell. Where the high surface area photovoltaic cell 104 has multiple cavitations, (one of many examples of which is shown), the device 100 can be referred to as an ultra-supercell.

The resulting high surface area photovoltaic cell 104 can be operationally connected to the photovoltaic cell substrate 106.

In the example of FIG. 1, the photovoltaic cell substrate 106 is the portion of the device 100 that, in operation, will be on the side facing away from the light source, which may also be referred to as the bottom or back, of the photovoltaic module. The substrate 106 can be formed from any applicable material, and the high surface area photovoltaic cell 104 can be formed on top of the substrate 106. It is expected that the substrate 106 will be rigid and load-bearing in typical applications. Alternatively, the substrate 106 can include a flexible thin film. It is theoretically possible that a high surface area photovoltaic cell 104 could be formed without a substrate, but a substrate is generally desirable to facilitate electrical connections and operationally connecting the photovoltaic cell substrate 106 to a module.

In the example of FIG. 1, the device 100 can have additional components that are not shown. For example, photovoltaic cells must normally be electrically coupled to one another when assembled into a photovoltaic module. The device 100 can include components associated with the electrical coupling. As another example, the high surface area photovoltaic cell 104 can be covered with a protective material prior to incorporation into a photovoltaic module. Such a cover might help to avoid damage during the manufacturing process prior to assembly, or to provide redundant protection, in addition to the cover normally provided when assembling cells into modules, to avoid damage from in transport, during installation, and/or after installation. It is possible to omit a protective cover. Typically, if a cell does not have a protective cover, one will be added prior to deployment of the cell in a photovoltaic module.

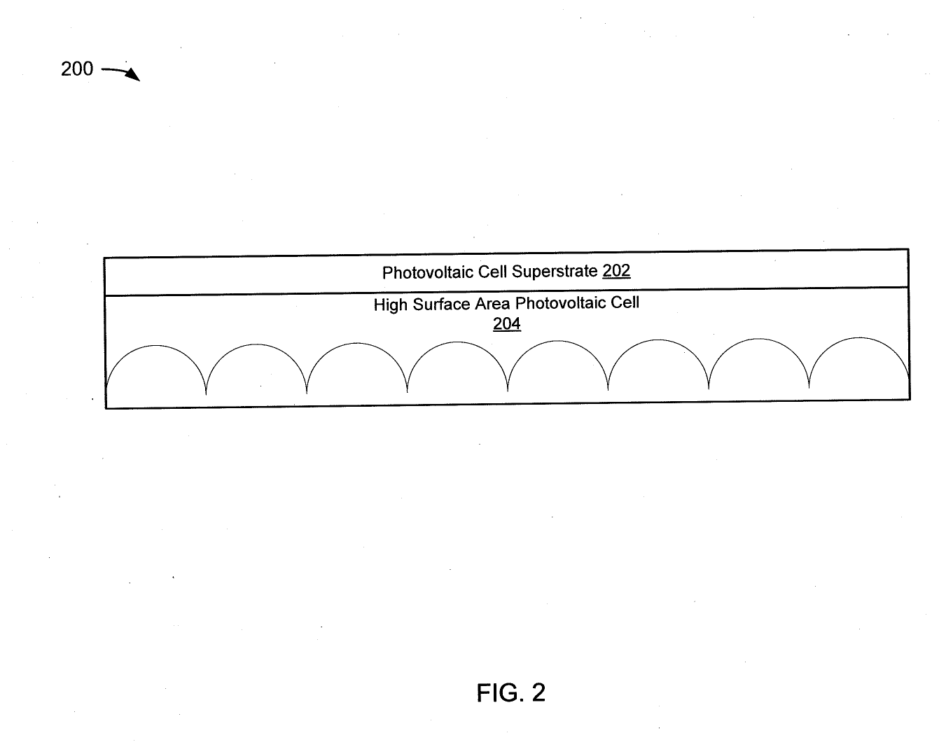

FIG. 2 depicts an example of a high surface area photovoltaic cell device 200 with superstrate. The device 100 includes a photovoltaic cell superstrate 202 and a high surface area photovoltaic cell 204. In the example of FIG. 2, the photovoltaic cell superstrate 202 is the portion of the device 200 that, in operation, will be on the light-facing side of the photovoltaic module. The superstrate 202 can be formed from any applicable material, and the high surface area photovoltaic cell 204 can be formed under of the superstrate 202. (It may be noted that “under,” “in front of,” et al. are intended to describe relative positions in operation, and are not descriptive of positioning of components during the manufacturing or assembly process.) The superstrate 202 can be load-bearing in typical applications, and can be flexible or rigid, but will have to allow light to pass through and is expected to be transparent for this reason.

In the example of FIG. 2, the device 200 can have additional components that are not shown. For example, photovoltaic cells must normally be electrically coupled to one another when assembled into a photovoltaic module. The device 200 can include components associated with the electrical coupling. As another example, the high surface area photovoltaic cell 204 can be covered with a protective material prior to incorporation into a photovoltaic module on the underside of the cell, and/or the photovoltaic cell superstrate 202 could be covered with a protective layer. It is possible to omit a protective cover. Typically, if a cell does not have a protective cover, one will be added prior to deployment of the cell in a photovoltaic module, or the photovoltaic cell superstrate 202 itself might act as a protective cover to the high surface area photovoltaic cell 204 underneath.

In the example of FIG. 2, the high surface area photovoltaic cell 204 is the portion of the device that, in operation, will be on the light-facing side of a photovoltaic module, but the photovoltaic cell superstrate 202 will be on top of the high surface area photovoltaic cell 204 on the light-facing side. The texture on the top of the high surface area photovoltaic cell 204 is intended to be illustrative in nature, but various cavitational shapes are possible that do not resemble the semi-circular humps that are depicted. The design goal of the surface is to increase the amount of light that hits a surface area of the high surface area photovoltaic cell 204.

An advantage of the high surface area photovoltaic cells described in FIGS. 1-2 is that they can increase surface area impacted by light. However, manufacturing costs associated with high surface area photovoltaic cells are believed to be higher than that of relatively flat cells. So, depending upon design criteria, the cells could be designed without the high surface area texture and assembled into three-dimensional modules to increase the amount of surface area of the module.

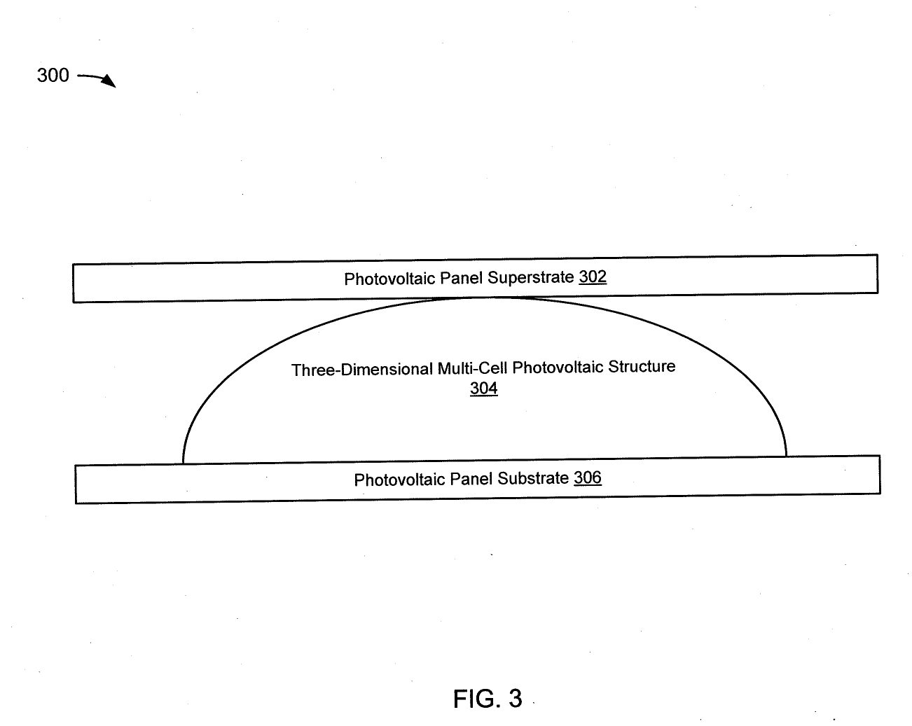

FIG. 3 depicts an example of a photovoltaic panel 300 with a three-dimensional multi-cell photovoltaic structure. The panel 300 includes a photovoltaic panel superstrate 302, a three-dimensional multi-cell photovoltaic structure 304, and a photovoltaic panel substrate 306. In the example of FIG. 3, the photovoltaic panel superstrate 302 is a transparent material, such as glass. In a specific implementation, the photovoltaic panel superstrate 302 is flat and rigid, which is expected to be cheaper to manufacture and easier to keep clean than a textured and/or flexible surface. A rigid surface is also likely to be correlated with superior protection of internal components of the panel 300 compared to that of a flexible surface.

The photovoltaic panel superstrate 302 can have a film covering the light-facing side for additional protection or to form a one-way mirror that enables light to enter relatively easily, but tends to bounce light reflected off of the internal components back toward the internal components. The photovoltaic panel superstrate 302 can also have a film covering the inside of the photovoltaic panel superstrate 302, which is less likely to be protective in nature because it is underneath the superstrate, but can have reflective properties. It is possible to take advantage of reflective materials, such as those that are used in “mirror” sunglasses, to increase the amount of reflected light that is bounced back to be harvested. Moreover, materials that have adequate reflective properties, but absorb certain light frequencies can still be used with cells that are tuned to take advantage of other light frequencies that are not impacted by the reflective coating.

In the example of FIG. 3, the three-dimensional multi-cell photovoltaic structure 304 comprises cells that are arranged in a three-dimensional format. A three dimensional structure can have greater surface area than a two dimensional structure, assuming even moderately careful design and placement, with respect to incident light. The cells that make up the three-dimensional multi-cell photovoltaic structure 304 need not be supercells (or ultra-supercells), but the panel 300 still takes advantage of higher surface area per unit of area than if the cells were arranged on a horizontal plane. So more power can be generated from the panel 300 per unit of area. This can be advantageous for space-constrained implementations. The three-dimensional multi-cell photovoltaic structure 304 can also form an interesting pattern, much like a sculpture, making the placement of the panel 300 in certain areas more aesthetically pleasing. The multi-cell three-dimensional structure could combine both three-dimensional and flat portions, the combination of which could be referred to as a multi-cell three-dimensional structure when considered as a whole.

Where the photovoltaic panel superstrate 302 has a one-way reflective coating, the three-dimensional multi-cell photovoltaic structure 304 can be formed to take advantage of, for example, reflecting light that is received at an angle perpendicular to the superstrate to be directed at an angle that is not perpendicular with respect to the substrate. Ideally, the three-dimensional multi-cell photovoltaic structure would not reflect light, but it is typical for a cell to reflect more light than it absorbs. So attempting to harvest the reflected light without increasing the amount of real estate needed for the panel would appear to be advantageous. Since it is known that one-way reflective surfaces will reflect more light that is incident at a first angle than light that is incident at a second angle, the three-dimensional multi-cell photovoltaic structure 304 can be designed to increase the likelihood that the reflected light is incident at the first angle on the internally reflective surface.

In the example of FIG. 3, the photovoltaic panel substrate 306 is a flat, rigid material that is likely to be designed to improve the durability of the panel 300. Since the substrate is under the three-dimensional multi-cell photovoltaic structure, it is unlikely to have reflective properties. Indeed, if light strikes the photovoltaic panel substrate 306, that means the three-dimensional multi-cell photovoltaic structure 304 could have been extended to cover that area. Obviously, more energy can be generated when light strikes a photovoltaic cell than an area that is simply reflective, which will still absorb some light since reflectors are not perfectly reflective in practical implementations.

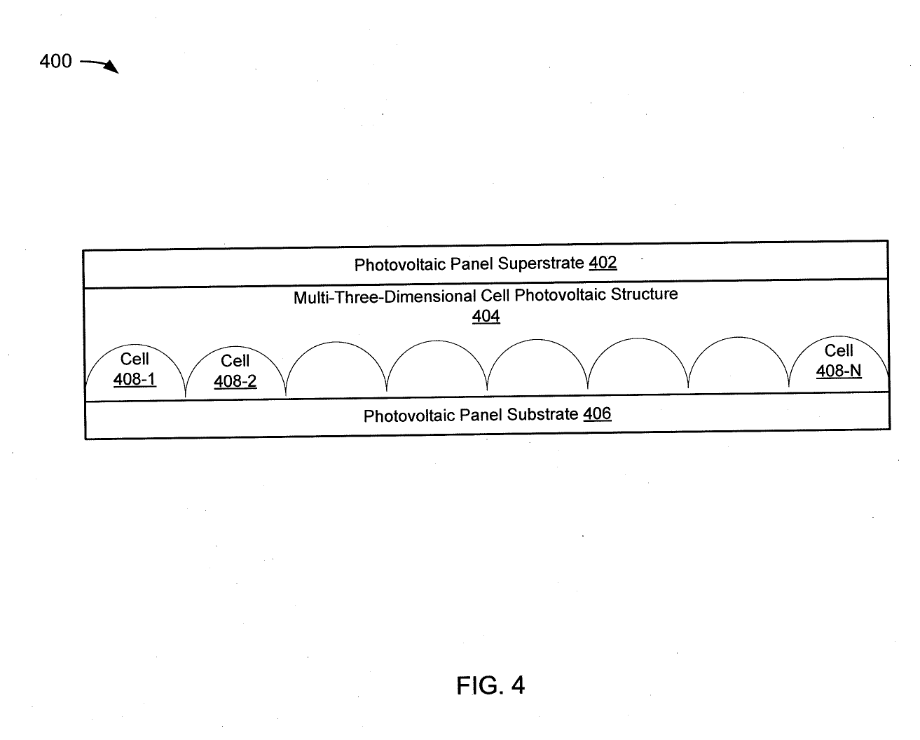

FIG. 4 depicts an example of a photovoltaic panel 400 with a multi-three-dimensional cell photovoltaic structure. The panel 400 includes a photovoltaic panel superstrate 402, a multi-three-dimensional cell photovoltaic structure 404, and a photovoltaic panel substrate 406. The superstrate 402 and the substrate 406 can be similar to the superstrate 302 and substrate 306 of FIG. 3. Just as the example of FIG. 3 is not intended to show a particular shape for a multi-cell photovoltaic cell structure (it is depicted as a half-globe, but could have one of many applicable shapes), the example of FIG. 4 is not intended to show a particular shape for each of the multiple cells. However, FIG. 4 is intended to show that the cells themselves can have a three-dimensional structure such that the amount of light incident on each cell is greater than if the cell were flat. The shape of the cells could be more subdued than is illustrated. For example, the cells could be “textured” such that the cell has multiple raised portions, potentially even raised so slightly such that a human looking at the cell would not notice that the cell is textured.

In the example of FIG. 4, the multi-three-dimensional cell photovoltaic structure 404 includes multiple supercells 408-1 to 408-N (collectively referred to as supercells 408). The supercells can be laid out in a horizontal plane along the substrate 406. There are advantages to using uniform cells, particularly as it relates to manufacturing efficiency, but the supercells 408 could have multiple different sizes and shapes. For example, there could be a relatively large central cell surrounded by relatively smaller cells around the larger cell, multiple relatively large cells surrounded by multiple relatively smaller cells, or some other applicable combination of larger and smaller cells. The concepts of FIG. 3 and FIG. 4 could also be used to create a multi-cell three-dimensional structure combined with multiple three-dimensional cells in a single panel.

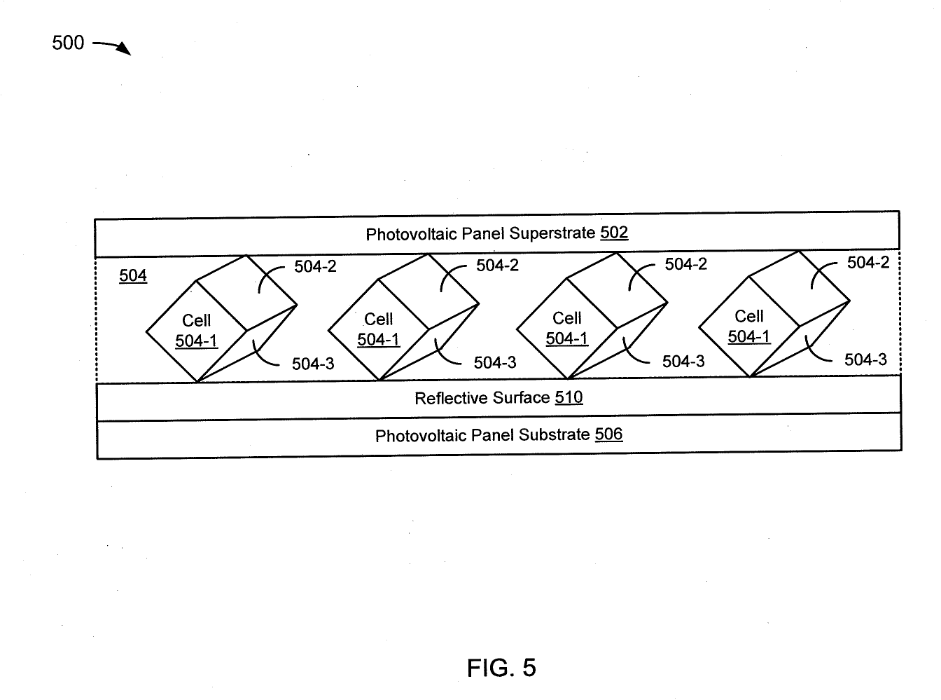

FIG. 5 depicts an example of a photovoltaic panel 500 with a three-dimensional multi-cell photovoltaic structure and internal reflective surface. The panel 500 includes a photovoltaic panel superstrate 502, a three-dimensional multi-cell photovoltaic structure 504, a photovoltaic panel substrate 506, and a reflective surface 510. The superstrate 502 and substrate 506 can be similar to those described previously with reference to FIGS. 3 and 4.

In the example of FIG. 5, the three-dimensional multi-cell photovoltaic structure 504 includes multiple cubes that each include cells 504-1 to 504-6 (collectively, the cell structures 504). In this example, the cell structures 504 are in the shape of a cube, though any applicable polyhedron could be formed. An advantage of cubes (or other shapes formed by same-sized cells) is that the cells can be manufactured more easily than if multiple different-sized cells were used to form the structure, though multiple different-sized cells could be used.

In the example of FIG. 5, the cell structures 504 are positioned over the reflective surface 510. The sides of the cells structures 504 need not be supercells (or ultra-supercells). Light that passes through the photovoltaic panel superstrate 502, which could have an internally reflective surface as described previously, is reflected back and at least some of the light will presumably be incident upon the underside of the cell structures 504. The relatively dense surface area of the cells per unit area of the panel also has a natural ventilation effect because the cells are raised and electricity can pass through the substrate (or, less likely, the superstrate) at a point or small area that can be exposed to the air under the substrate an what simulates, or is actually, a cooling fin. It may be desirable to connect the cell structures 504 in a grid to reach desired electrical parameters, though the example of FIG. 5 illustrates cells structures 504 that do not appear to be operationally connected.

It is typically ideal to have light strike cells, rather than reflective surfaces that reflect the light back to the cells. However, by using reflective surfaces, it has been shown in proof of concept that relatively low cost cells can be used to form cell structures that have greater surface area than if the cells were laid out on a plane. Where the cell structures are relatively close together, it may not be “worth it” to add photovoltaic modules along the photovoltaic panel substrate 506. So, instead, a less expensive reflective surface may be adequate to angle incident light underneath the cells 504. This gives results in more effective panels that take up relatively less horizontal area. It may be noted that solar panels exist that do effectively make use of focusing or reflecting light using lenses or mirrors. However, such systems employ mechanisms that are located above the panel and direct the light toward the panel, rather than using mechanisms within the panel itself to reflect light towards the cells. In some implementations, external mechanisms may not be desirable.

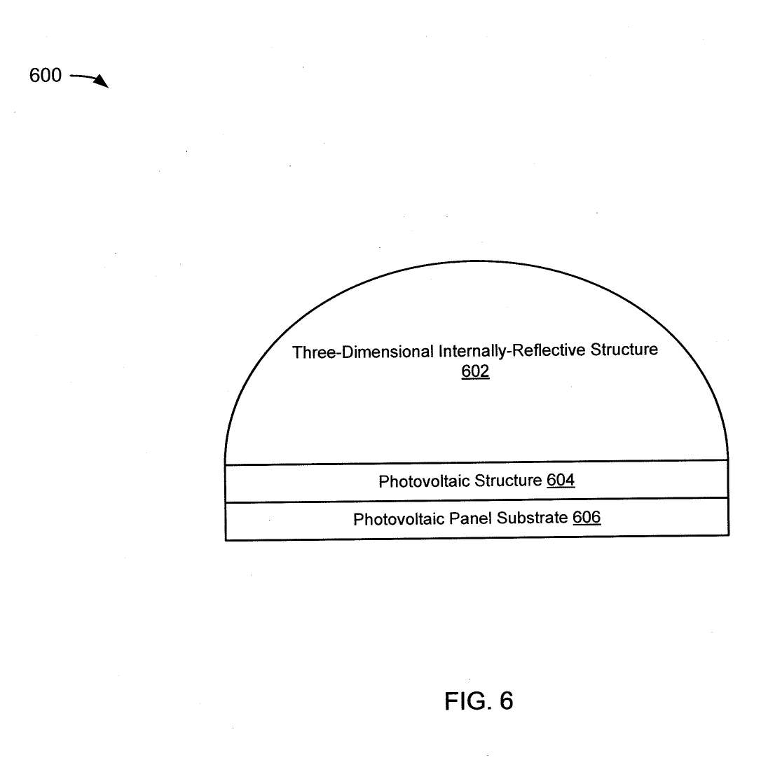

FIG. 6 depicts an example of a photovoltaic panel 600 with a three-dimensional internally-reflective structure. The panel 600 is intended to illustrate that a panel cover can replace a superstrate. The panel 600 includes a three-dimensional internally reflective structure 602, a photovoltaic structure 604, and a photovoltaic panel substrate 606. The photovoltaic structure 604 can be similar to the photovoltaic structures 304, 404, 504, described above with reference to FIGS. 3-5.

The three-dimensional internally-reflective structure 602 can enable light that passes through the structure bounce around inside the volume between the structure 602 and the photovoltaic structure 604, increasing the amount of light that is incident upon the photovoltaic structure 604. In addition, the three-dimensional internally reflective structure 602 can be implemented to be load bearing, which can increase the durability of the panel 600.

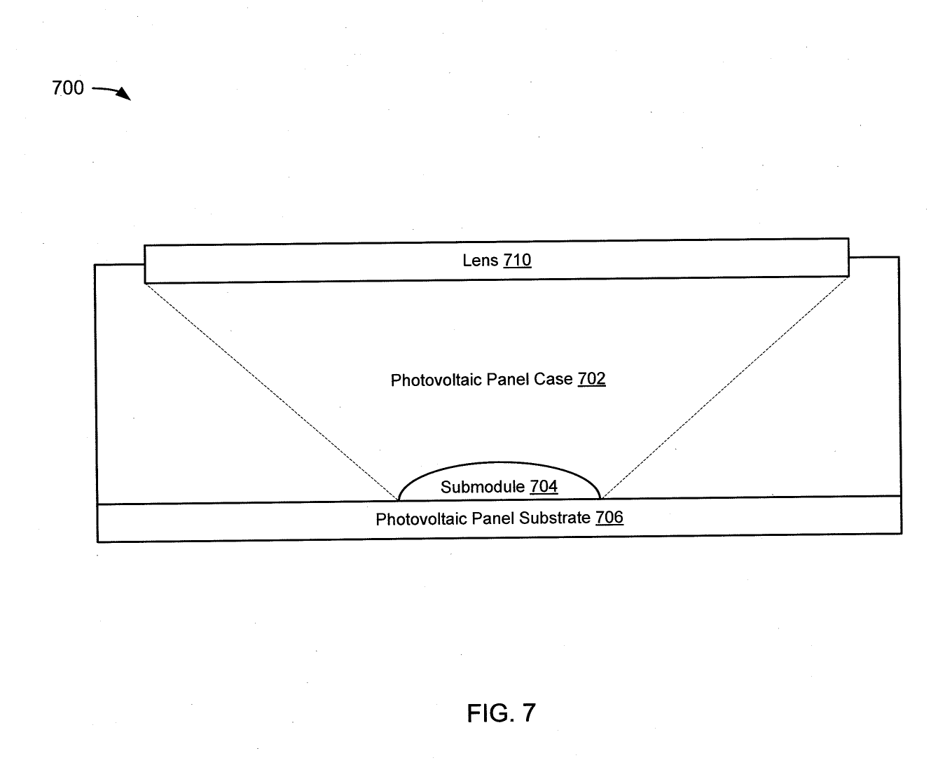

FIG. 7 depicts an example of a concentrating photovoltaics (CPV) photovoltaic panel 700. Unlike known CPV systems, the CPV photovoltaic panel 700 is a monolithic structure, making it convenient to use in places where an external light focusing mechanism would be undesirable, whether due to environmental factors or aesthetics. The CPV photovoltaic panel 700 includes a photovoltaic panel case 702, a submodule 704, a photovoltaic panel substrate 706, and a lens 710. The photovoltaic panel substrate 706 can be similar to the photovoltaic panel substrates 306, 406, 506, 606, described previously with reference to FIGS. 3-6.

The photovoltaic panel case 702 can protect the internal components of the panel 700 in a manner similar to a superstrate. The case can optionally include other components described above with reference to FIGS. 3-6, such as internally reflective surfaces.

In the example of FIG. 7, the submodule 704 is located within the photovoltaic panel case 702. Unlike previously described panels that make use of multiple cells covering a substrate surface, it may be possible to meet desirable operational parameters with cells that do not span the entire surface of the photovoltaic panel substrate 706 because light is focused on the submodule 704. Since a smaller number of cells can be used in the panel, higher cost, more efficient photovoltaic technology can be used within economic constraints. Moreover, the three-dimensional form of the submodule 704 can enable light that is focused to around the edges of the submodule 704 to strike more surface area of the submodule 704 than if the submodule were flat. This is particularly advantageous in relatively flat panel implementations, which is the norm. Advantageously, the lens 710 only needs to refract light by a sufficient amount to make the use of fewer cells within the panel 700, and the amount of refraction can be selected based upon weighing the difficulty of implementing a highly refractive lens and the cost of implementing more cells within the submodule 704.

The submodule 704 may include a three-dimensional multi-cell structure comprising cells such as were described previously with reference to FIGS. 1 and 2. Alternatively, a flat cell could be used. A panel could also alternatively include multiple CPV subpanels operationally connected.

In the example of FIG. 7, the lens 710 is operationally connected to the photovoltaic panel case 702 to form a monolithic structure including the photovoltaic panel substrate 706 and the internal components. The lens 710 focuses light on the photovoltaic cell 704. It may be desirable to use a lens that covers a relatively large surface area to ensure the light is directed appropriately. Also, multiple lenses and multiple cells could be implemented in a single panel (not shown), if it is desirable to use smaller lenses or for some other reason. The lens 710 need only focus light sufficient to meet operational parameters, which are expected to cause light to preferentially strike the supercell 704.

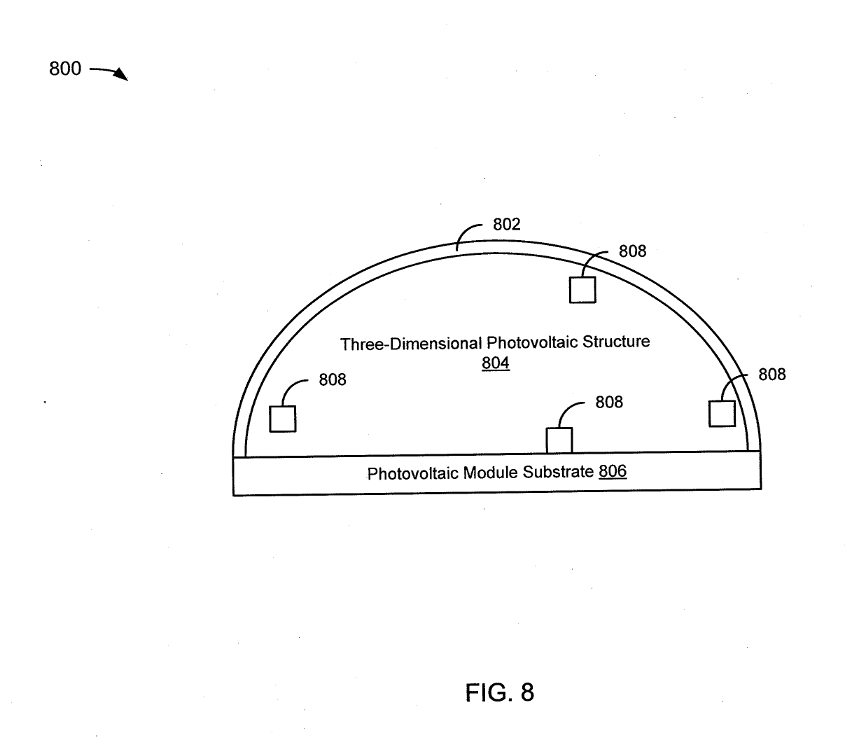

FIG. 8 depicts an example of a three-dimensional photovoltaic module 800. The example of FIG. 8 is intended to illustrate an implementation in which photovoltaic cells form a three-dimensional structure along an outer shell. The three-dimensional photovoltaic module 800 includes a photovoltaic module cover 802, a three-dimensional photovoltaic structure 804, a photovoltaic module substrate 806, and a plurality of cells 808. The photovoltaic module substrate can be similar to the substrates 306, 406, 506, 606, 706, described previously with reference to FIGS. 3-7.

In the example of FIG. 8, the photovoltaic module cover 802 can be implemented as a load-bearing shell under which the three-dimensional photovoltaic structure 804 is positioned. The three-dimensional photovoltaic structure 804 comprises the photovoltaic cells 808, which are protected from the environment by the photovoltaic module cover 802. The photovoltaic cells 808 can be similar to the photovoltaic cells described previously with reference to FIG. 1 or 2. Alternatively some other applicable cell could be used.

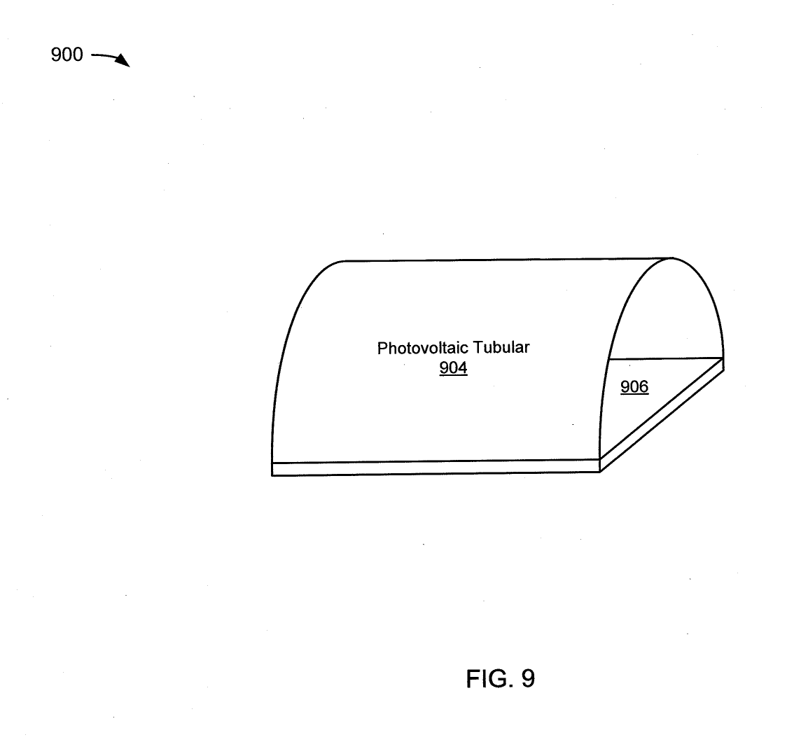

FIG. 9 depicts an example of a tubic photovoltaic module 900. The module 900 includes a photovoltaic tubular structure 904 and a photovoltaic module substrate 906. The photovoltaic module substrate 906 can be similar to the substrates 306, 406, 506, 606, 706, 806, described previously with reference to FIGS. 3-8. The photovoltaic tubular structure 904 comprises cells (not shown), which can be supercells or ultra-supercells. Alternatively, another applicable type of cell could be used. The photovoltaic tubular structure 904 can be covered with a substrate (not shown).

The example of FIG. 9 is intended to show an example of a three-dimensional photovoltaic module that has a shape other than a dome. Any applicable shape could be used, but the tubular, or half-tubular, shape is expected to be relatively easy to manufacture. While a dome is superior to a tube in providing more surface area per unit of area the panel covers, the lower manufacturing costs of a half-tube can make the tubic voltaic module 802 a good choice for certain implementations. However, when the tubular photovoltaic module 900 is implemented as a solar panel, it may be desirable to add a rotating platform to position the tube so as to have the sun strike the sides rather than the ends. Such a platform is less important for a dome, which has relatively good surface area facing the sun given its form factor.

Advantageously, a tubular shape can facilitate ventilation. The ventilation can be from wind or generated by a fan that blows or sucks air through the tunnel formed by the substrate and the tube. This is expected to be superior to the ventilation for flat panels, even if a fan is used.

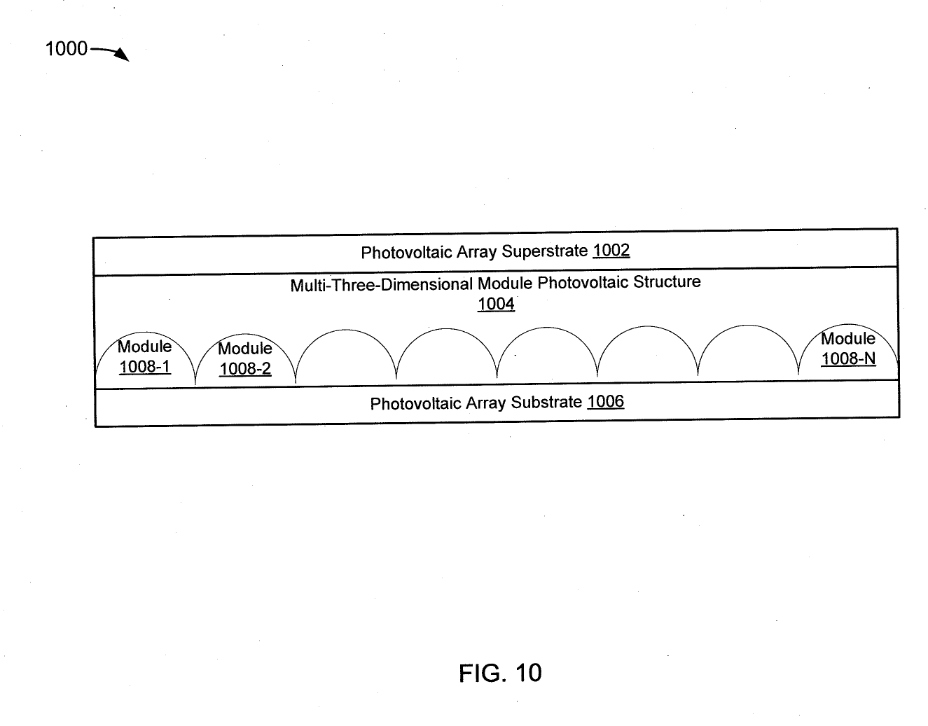

Any of the photovoltaic modules described with reference to FIGS. 3-9 can themselves be arranged in a three-dimensional photovoltaic array, as well. FIG. 10 depicts an example of a three-dimensional photovoltaic array 1000. The three-dimensional photovoltaic array 1000 includes a photovoltaic array superstrate 1002, a multi-three-dimensional module photovoltaic structure 1004, a photovoltaic array substrate 1006, and photovoltaic modules 1008-1 to 1008-N (collectively referred to as modules 1008). In the example of FIG. 1, the photovoltaic array substrate 1002 can be implemented with materials that protect the underlying components and that do not degrade performance of the three-dimensional photovoltaic array 1000 by substantially reflecting or absorbing light frequencies that can be used by the modules 1008 to generate power. As with the photovoltaic modules described previously, the photovoltaic array superstrate 1002 is, in accordance with current techniques, likely to be of glass or a mixture of glass and plastic. The multi-three-dimensional module photovoltaic structure 1004 can include the modules 1008, each or any of which can be modules such as is described with reference to FIGS. 3-9, or some other applicable module. The modules 1008 are operationally connected to the photovoltaic array substrate 1006.

In the various systems described above, the distance between three-dimensional modules, or portions of the three-dimensional modules, can vary depending upon implementation-, application- and/or configuration-specific parameters.

Systems described herein may be implemented on any of many possible hardware, firmware, and software systems. Algorithms described herein are implemented in hardware, firmware, and/or software that is implemented in hardware. The specific implementation is not critical to an understanding of the techniques described herein and the claimed subject matter.

As used in this paper, the term “embodiment” means an embodiment that serves to illustrate by way of example but not necessarily by limitation.

It will be appreciated to those skilled in the art that the preceding examples and embodiments are exemplary and not limiting to the scope of the present invention. It is intended that all permutations, enhancements, equivalents, and improvements thereto that are apparent to those skilled in the art upon a reading of the specification and a study of the drawings are included within the true spirit and scope of the present invention. It is therefore intended that the following appended claims include all such modifications, permutations and equivalents as fall within the true spirit and scope of the present invention.

1. A photovoltaic structure comprising:
a photovoltaic module substrate;
a photovoltaic module cover;
a plurality of photovoltaic cells arranged in a three-dimensional shape within the photovoltaic module substrate and the photovoltaic module cover.

2. The photovoltaic structure of claim 1, wherein the photovoltaic module cover forms a relatively flat surface under which the plurality of photovoltaic cells are arranged.

3. The photovoltaic structure of claim 1 wherein the three-dimensional shape includes a plurality of relatively flat photovoltaic cells.

4. The photovoltaic structure of claim 1, wherein the three-dimensional shape includes a plurality of three-dimensional photovoltaic cells arranged in a co-planar fashion over the photovoltaic module substrate.

5. The photovoltaic structure of claim 1, wherein the three-dimensional shape includes a plurality of multi-cell structures arranged in a co-planar fashion over the photovoltaic module substrate.

6. The photovoltaic structure of claim 5, wherein one or more of the multi-cell structures are formed from relatively flat photovoltaic cells.

7. The photovoltaic structure of claim 5, wherein one or more of the multi-cell structures are formed into a polyhedron.

8. The photovoltaic structure of claim 1, further comprising a reflective surface coupled to the photovoltaic module substrate, wherein light that is reflected off of the photovoltaic cells or that is not initially incident on the photovoltaic cells is at least in part reflected back to one or more of the photovoltaic cells.

9. The photovoltaic structure of claim 1, wherein the photovoltaic module cover includes an internally reflective surface, wherein light that passes through the photovoltaic module cover and is reflected back toward the photovoltaic module cover is at least in part reflected back inward in the direction of, or at an angle toward, the photovoltaic module substrate.

10. The photovoltaic structure of claim 1, wherein the photovoltaic module cover forms a three-dimensional shape along an internal surface of which the plurality of photovoltaic cells are arranged.

11. The photovoltaic structure of claim 1, wherein the photovoltaic module cover includes a lens, wherein the lens focuses light toward one or more of the plurality of photovoltaic cells.

12. The photovoltaic structure of claim 1, wherein the plurality of photovoltaic cells are located within a photovoltaic module case.

13. The photovoltaic structure of claim 1, wherein a cell of the plurality of photovoltaic cells is a high surface area photovoltaic cell.

14. The photovoltaic structure of claim 1, further comprising a plurality of photovoltaic modules that together form a three-dimensional shape.

15. The photovoltaic structure of claim 1, wherein a photovoltaic module of the photovoltaic structure includes a solar panel.

16. A photovoltaic module comprising:
a photovoltaic module substrate;
a photovoltaic module case coupled to the photovoltaic module substrate;
a lens coupled to the photovoltaic module case;
a photovoltaic cell, wherein, in operation, light is focused by the lens in the direction of the photovoltaic cell.

17. The photovoltaic module of claim 16, wherein the photovoltaic cell is a high surface area photovoltaic cell.
